(19) United States
(12) Patent Application Publication
(10) Pub. No.: US 2016/0126385 A1
(43) Pub. Date: May 5, 2016

(54) ROOF PANEL HAVING SOLAR CELL OF VEHICLE

(71) Applicant: Hyundai Motor Company, Seoul (KR)

(72) Inventors: Won Jung Kim, Seoul (KR); Moon Jung Eo, Seoul (KR); Sol Kim, Seoul (KR); Hae Yoon Jung, Seoul (KR); Sang Hak Kim, Seoul (KR); Mi Yeon Song, Seoul (KR)

(21) Appl. No.: 14/868,768

(22) Filed: Sep. 29, 2015

(30) Foreign Application Priority Data
Oct. 31, 2014 (KR) 10-2014-0149776

(51) Int. Cl. H01L 31/048; H01L 51/42; H01L 31/0352; B60L 8/00; H01L 31/0368; H01L 31/0296; H01L 31/0304; B60J 7/043; H01L 31/0376; H01G 9/20

(52) U.S. Cl. CPC H01L 31/0488; H01L 31/03762; H01L 51/42; H01L 51/4253; H01L 31/035218; H01G 9/2031; H01L 31/03682; H01L 31/0296; H01L 31/03046; B60J 7/043; B60L 8/003

(57) ABSTRACT

A roof panel of a vehicle is equipped with a solar cell module that is capable of satisfying an opening sense of the roof panel and preventing a voltage drop due to contact between heterogeneous solar cells. The solar cell module has the heterogeneous solar cell modules simultaneously mounted, and maintains output voltages of the heterogeneous solar cells to be the same by providing a plurality of cells in at least one of the solar cell modules, or individually controlling power output from the same kinds of solar cells by electric wire parts individually connected to the heterogeneous solar cells to maximize performance of the solar cell.

### CROSS-REFERENCE TO RELATED APPLICATION

This application claims under 35 U.S.C. §119(a) the benefit of Korean Patent Application No. 10-2014-0149776 filed on Oct. 31, 2014, the entire contents of which are incorporated herein by reference.

### BACKGROUND

(a) Technical Field

The present invention relates to a roof panel having a solar cell of a vehicle, more particularly, a roof panel capable of satisfying a sense that the roof panel is opened by having heterogeneous solar cell modules simultaneously mounted therein and maximizing performance of the solar cell by individually controlling heterogeneous solar cells.

(b) Description of the Related Art

Green cars such as a hybrid vehicle, an electric vehicle, and a fuel cell vehicle have been developed in recent years. Attempts to apply a solar cell to these car models have been variously conducted.

In particular, in the case of applying the solar cell to a sun roof panel or a panorama sun roof panel of a vehicle, the sense of opening the existing sun roof may be maintained and solar energy may be used in various applications. As a result, attempts to apply the solar cell to the sun roof panel, the panorama sun roof panel, and the like of the vehicle have been conducted.

Generally, the sun roof or the panorama sun roof panel of the vehicle is made of tempered glass and a frame, and an outside portion of the tempered glass is coated with ceramic to prevent the frame inside the vehicle, an electrode connected to the solar cell, and an electric wire from being visible from the outside.

In the case of the existing roof panel having a silicon solar cell, the silicon solar cell is mounted at a central portion (middle portion of the tempered glass to which the ceramic coating is not applied) of a rear surface of the roof panel but has not widely been propagated due to a problem of cost, lack of opening sense, design reduction, and the like. As a result, attempts to replace the silicon solar cell with a dye-sensitive solar cell have been conducted.

The dye-sensitive solar cell may be manufactured at lower cost, with a transparent electrode, in various designs, and the like. Accordingly, research to apply the dye-sensitive solar cell to various applications has been conducted.

Compared with the silicon solar cell, the dye-sensitive solar cell is cheaper, has a better opening sense, and accommodates additional colors, but has lower overall solar cell performance.

As such, since energy efficiency between the heterogeneous solar cells is different, when a driver is connected to a charger by a single electric wire part by contacting between the respective solar cells, like a solar cell having a small voltage value, a total of the voltage values generated from solar cells are converged. Therefore, in the case of using the heterogeneous solar cells, there is a problem of energy efficiency due to a contact between the solar cells.

Korean Patent No. 10-0711566 in the related art discloses a method of bonding a solar cell module to a sun roof of a vehicle using a laminator device as a method for manufacturing a solar cell module for a sun roof of a vehicle.

However, Korean Patent No. 10-0711566 has a disadvantage in that an opaque solar cell is attached to a transparent window of the existing sun roof and thus the opening sense may not be provided to a driver.

The above information disclosed in this Background section is only for enhancement of understanding of the background of the invention and therefore it may contain information that does not form the prior art that is already known in this country to a person of ordinary skill in the art.

### SUMMARY

The present invention provides a roof panel having a solar cell in which a first solar cell which may provide an opening sense is mounted at a central portion of the roof panel and a second solar cell having excellent solar cell performance is mounted at an edge portion of the roof panel to maximize performance of the solar cell while securing the opening sense of the roof panel and prevent contact between the first solar cell and the second solar cell and an electric wire part connected to each solar cell so as to prevent a voltage drop that occurs due to a contact between heterogeneous solar cells.

In one aspect, the present invention provides a roof panel having a solar cell of a vehicle in which heterogeneous solar cells are disposed in a roof glass, including: a first solar cell configured to be mounted at a central portion of the roof glass; and a second solar cell having transparency lower than that of the first solar cell configured to be mounted at an edge portion of the roof glass, wherein upper and lower surfaces of the first solar cell and the second solar cell are sequentially stacked with a bonding film and the roof glass, at least one of the first solar cell and the second solar cell is configured of a plurality of cells and the plurality of cells of the solar cell are connected in series and in parallel so that output voltages of the solar cells are the same, and the first solar cell and the second solar cell are adjacently positioned to each other, maintaining a gap to prevent the first solar cell and the second solar cell from contacting each other.

In a preferred embodiment, the first solar cell and the second solar cell may be formed at different thicknesses and may further a filling film to offset a difference in thickness between the first solar cell and the second solar cell.

In another preferred embodiment, in the case of the solar cell configured of the plurality of cells, the cells may be the same size.

In still another preferred embodiment, as the first solar cell, any one selected from a dye-sensitive solar cell, an amorphous silicon solar cell, an organic solar cell, a perovskite-based solar cell, and a quantum dot solar cell may be used or a combination of at least two thereof may be used.

In yet another preferred embodiment, as the second solar cell, any one selected from a crystalline silicon solar cell, a cadmium-telluride (CdTe) solar cell, and a copper-indium-gallium-selenium (CIGS) solar cell may be used or a combination of at least two thereof may be used.

In still yet another preferred embodiment, a constant gap between the first solar cell and the second solar cell may be filled with an insulator.

In another aspect, a roof panel having a solar cell of a vehicle in which heterogeneous solar cells are disposed in a roof glass, including: a first solar cell configured to be mounted at a central portion of the roof glass; and a second solar cell having transparency lower than that of the first solar cell configured to be mounted at an edge portion of the roof glass; a first electric wire part configured to be connected to an electrode of the first solar cell; a second electric wire part configured to be connected to an electrode of the second solar cell; and a plurality of controllers configured to be connected to the first electric wire part and the second electric wire part, respectively, wherein upper and lower surfaces of the first solar cell and the second solar cell are stacked with a bonding film, and the first solar cell and the second solar cell are adjacently positioned to each other, maintaining a gap to prevent the first solar cell and the second solar cell from contacting each other.

In a preferred embodiment, the plurality of controllers may control a connection between a charger and a driver depending on outputs of each solar cell.

In another preferred embodiment, the controller may receive information measured by a positional information sensor of the vehicle which measures altitude information of the sun, a geomagnetic sensor which measures a slope of the vehicle, and a tilt sensor which measures a slope of the roof panel and control the slope of the roof channel depending on the received information.

In still another preferred embodiment, the controller may be configured of a maximum power point tracking (MPPT) controller.

In still yet another preferred embodiment, as the first solar cell, any one selected from a dye-sensitive solar cell, an amorphous silicon solar cell, an organic solar cell, a perovskite-based solar cell, and a quantum dot solar cell may be used or a combination of at least two thereof may be used.

In further still another preferred embodiment, as the second solar cell, any one selected from a crystalline silicon solar cell, a cadmium-telluride (CdTe) solar cell, and a copper-indium-gallium-selenium (CIGS) solar cell may be used or a combination of at least two thereof may be used.

In further still yet another preferred embodiment, a constant gap between the first solar cell and the second solar cell may be filled with an insulator to prevent the first solar cell and the second solar cell from contacting each other.

According to the roof panel having a solar cell according to the exemplary embodiments of the present invention, the solar cell module is mounted between the upper plate of the roof glass and the lower plate of the roof glass to apply the solar cell module to the whole area of the roof panel to further expand the mounting area of the solar cell module than before, thereby expanding the photovoltaic area.

The first solar cell having a translucent property is used at the central portion of the roof panel and the second solar cell having transparency lower than that of the first solar cell is used at the edge portion of the roof panel, thereby providing the opening sense to the driver.

The contact between the first solar cell and the second solar cell is prevented and thus the voltage drop is prevented due to the contact between the respective solar cells, thereby efficiently using the performance of the solar cell.

The solar cells are separately controlled depending on the voltage difference between the respective solar cells by connecting the individual electric wire parts to the respective solar cells, thereby improving the photovoltaic performance.

Other aspects and preferred embodiments of the invention are discussed infra.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present invention may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

The above and other features of the invention are discussed infra.

### BRIEF DESCRIPTION OF THE DRAWINGS

The above and other features of the present invention will now be described in detail with reference to certain exemplary embodiments thereof illustrated in the accompanying drawings which are given hereinbelow by way of illustration only, and thus are not limitative of the present invention, and wherein:

FIG. 1 is a cross-sectional view of a roof panel having a solar cell of a vehicle;

FIG. 2 is a cross-sectional view of the roof panel of FIG. 1 having a filling film inserted into a gap thereof;

FIG. 3 is a diagram illustrating a roof panel which has a first solar cell applied to a panorama sun roof for a vehicle and a second solar cell configured of a plurality of cells, as an exemplary embodiment of the present invention;

FIG. 4 is a diagram illustrating a first electric wire part connected to the first solar cell and a second electric wire part connected to the second solar cell;

FIG. 5A is a diagram illustrating a connection by a controller of the roof panel having a solar cell including a single electric wire part;

FIG. 5B is a diagram illustrating a connection between the roof panel having a solar cell and a charger and a driver by the controller which is connected to the first electric wire part and the second electric wire part, respectively; and

FIG. 5C is a diagram illustrating a connection between only an output of the first solar cell and the charger and the driver by the first electric wire part.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

Hereinafter, exemplary embodiments of the present invention so as to be easily practiced by a person skilled in the art to which the present invention pertains will be described with reference to the accompanying drawings.

The present invention relates to a roof panel 10 of a vehicle configured by using a solar cell module and capable of maximizing performance of a solar cell while securing an opening sense of the roof panel while simultaneously using two kinds of solar cell modules. In particular, as used herein, the term “opening sense” (and similar terms) refers to the ability to sense that the roof panel of a vehicle has been opened, so as to distinguish between open and closed positions of the roof panel.

According to an exemplary embodiment of the present invention, a first solar cell 11 which may provide the opening sense is mounted at a central portion of the roof panel and a second solar cell 12 having excellent solar cell performance is mounted at an edge portion of the roof panel, and roof glass made of laminated glass instead of the existing roof glass made of tempered glass is used to maximize a photovoltaic area.

Generally, in the case of the laminated glass used at the front glass of the vehicle, two sheets of glasses are bonded to each other and a bonding film 13 made of ethylene vinyl acetate (EVA), ethylene tetrafluoroethylene (ETFE), polyvinylidene fluoride (PVDF), polydimethylsiloxane (PDMS), polyethylene terephthalate (PET), polyvinyl butyral (PVB), and the like which have more excellent impact elasticity, bursting strength, and tensile strength than glass is mounted between the two sheets of glasses. When composite molecular materials having excellent tensile force and elasticity like the bonding film 13 are laminated along with glass, the glass will crack like a spider web when applied with a strong shock but will not break.

Therefore, the roof panel 10 having a solar cell of a vehicle according to an exemplary embodiment of the present invention preferably is configured using a structure of the laminated glass instead of the existing tempered glass as the roof glass to which the solar cell is attached.

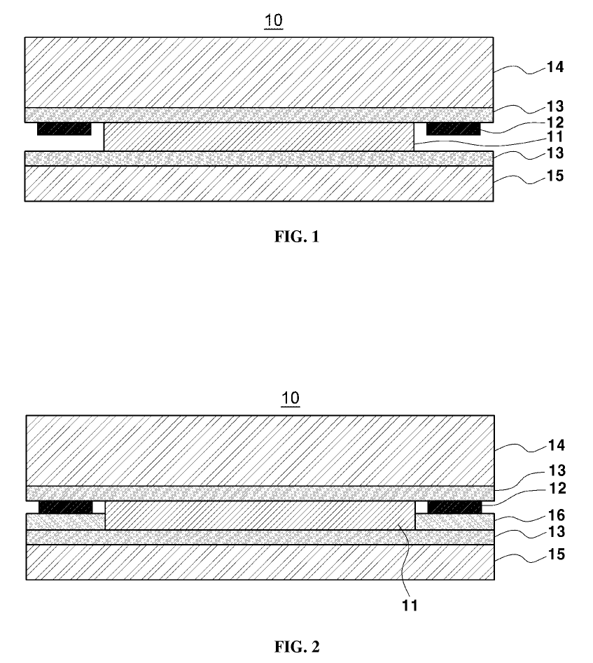

FIG. 1 is a cross-sectional view of the roof panel 10 having a solar cell according to the exemplary embodiment of the present invention. In the case of the roof panel according to the exemplary embodiment of the present invention, heterogeneous solar cells are disposed in the roof glass, in which a central portion of the roof glass is provided with a first solar cell 11, and an edge portion of the roof glass is provided with a second solar cell 12 having transparency lower than that of the first solar cell 11. In particular, both the first and second solar cells 11, 12 are generally transparent; however, the second solar cell 12 has lower transparency than the first solar cell 11. Also, both types of solar cells preferably are combined with the roof glass. Upper and lower surfaces of the first solar cell 11 and the second solar cell 12 are sequentially stacked with the bonding film 13 and the roof glass. Further, the first solar cell 11 and the second solar cell 12 are adjacently positioned to each other, maintaining a predetermined gap therebetween to prevent the first solar cell 11 and the second solar cell 12 from contacting each other.

Generally, when the heterogeneous solar cells having different light efficiencies and output voltages contact each other, the output voltage of the solar cell having a high voltage is converged to the solar cell having a low voltage. Therefore, according to the exemplary embodiment of the present invention, to maintain the efficiency of the solar cell having a high voltage output, the gap between the first solar cell 11 and the second solar cell 12 is maintained constantly. This may maintain the output voltage of the solar cell having relatively higher light efficiency, and thus the light efficiency of the configuration of the heterogeneous solar cells may be maintained at an optimal level. More preferably, an insulator may be inserted into a gap between the first solar cell 11 and the second solar cell 12 to prevent the solar cells from being conducted to each other.

As the first solar cell 11 which is positioned at the central portion of the roof, the solar cell having high transparency is used. Therefore, a translucent amorphous silicon solar cell is configured to maintain opening sense and lighting property of the roof panel. More preferably, the dye-sensitive solar cell, the amorphous silicon solar cell, a perovskite-based solar cell, an organic solar cell, a quantum dot solar cell, and the like may each constitute the first solar cell 11 or a combination thereof may constitute the first solar cell 11.

In the case of the second solar cell 12 which is positioned at the edge of the roof, the transparency is not an essential factor and therefore the second solar cell 12 may be configured using a crystalline silicon solar cell. In addition, the second solar cell 12 may be configured of a cell having light efficiency higher than that of the first solar cell 11. More preferably, compound-based solar cells such as a cadmium-telluride (CdTe) solar cell and a copper-indium-gallium-selenium (CIGS) solar cell may each constitute the second solar cell 12 and a combination thereof may constitute the second solar cell 12.

The roof glass is configured of an upper plate and a lower plate. To bond an upper plate 14 of the roof glass to a lower plate 15 of the roof glass, adhesives such as ethylene vinyl acetate (EVA), ethylene tetrafluoroethylene (ETFE), polyvinylidene fluoride (PVDF), polydimethylsiloxane (PDMS), polyethylene terephthalate (PET), polyvinyl butyral (PVB), and the like are used, which bonds the solar cell module between the upper plate 11 and the lower substrate 12.

FIG. 2 illustrates a structure in which the heterogeneous solar cells form a laminate layer. As described above, the heterogeneous solar cells may have a difference in thickness. Generally, the difference in thickness of the solar cells is equal to or more than 1 mm More preferably, the difference in thickness of the solar cells is equal to or more than 3 mm.

As described above, in the case of the roof channel 10 having a solar cell using a combination of the first solar cell 11 and the second solar cell 12, a thickness of the solar cell module configuring the first solar cell 11 and a thickness of the solar cell module configuring the second solar cell 12 may be different from each other. As described above, after each solar cell module is attached on the lower surface of the upper plate 14 of the roof glass, when the lower plate 15 of the roof glass is bonded, a step may occur, and therefore, when the lower plate of the roof glass is bonded on the solar cell module, the step may adversely affect the bonded portion.

According to the exemplary embodiment of the present invention, a step may occur between the first solar cell 11 and the second solar cell 12 which are adjacent to each other at the edge portion of the roof glass or the roof panel. A filling film 16 is inserted into a portion at which the step occurs to control a step occurring due to the difference in thickness between the first solar cell 11 and the second solar cell 12. The filling film 16 inserted to alleviate the step may be made of ethylene-vinyl acetate (EVA) and polyvinyl butyral (PVB).

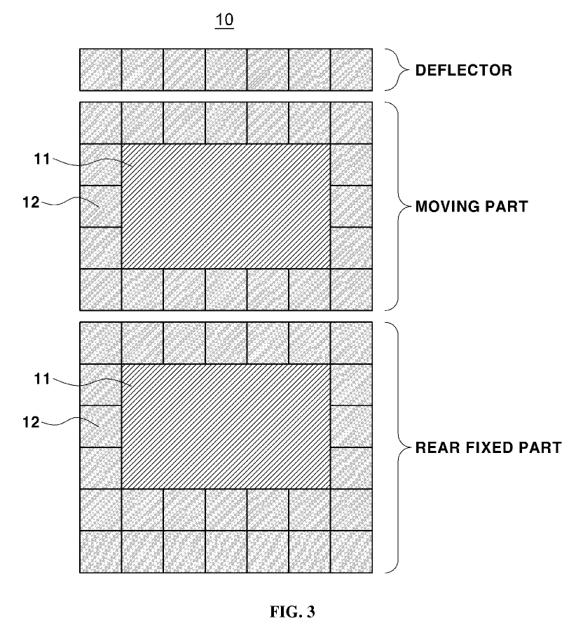

FIG. 3 is a front view of the roof panel 10 having a solar cell according to the exemplary embodiment of the present invention. The exemplary embodiment of the present invention includes the configuration of the first solar cell 11 and the second solar cell 12 on the roof panel which is configured by being divided into three. In the case of FIG. 3, as components of the panorama sun roof which is positioned at the roof of the vehicle, a deflector, a moving part, and a rear fixed part fixed to a rear of the roof of the vehicle are provided.

As illustrated in FIG. 3, the first solar cell 11 is disposed at central portions of the moving part and the rear fixed part which require the opening sense and the lighting property and the second solar cell 12 is disposed at an edge of the moving part, an edge of the rear fixed part, and the deflector.

In the case of the second solar cell 12, the edge of the moving part, the edge of the rear fixed part, and the deflector maintain a shape of a plurality of cells. More preferably, each cell has the same size to prevent an output from being reduced. As such, in the case of the solar cell configured of cells, a serial and parallel connection of each cell is configured and thus the output voltages of the heterogeneous solar cells may coincide with each other.

The electric wire parts which are connected to electrodes of the heterogeneous solar cells are configured to include a first electric wire part 17 which is connected to an electrode of the first solar cell 11 and a second electric wire 18 which is connected to an electrode of the second solar cell 12. However, when the first electric wire part 17 and the second electric wire part 18 are handled as a single wiring, the output voltage of the solar cell configured of cells and the output voltage of another solar cell may be set to be equal by the serial and parallel connection of the solar cells configured of a plurality of cells. Therefore, a power loss which occurs due to the difference in output voltages between the heterogeneous solar cells may be minimized.

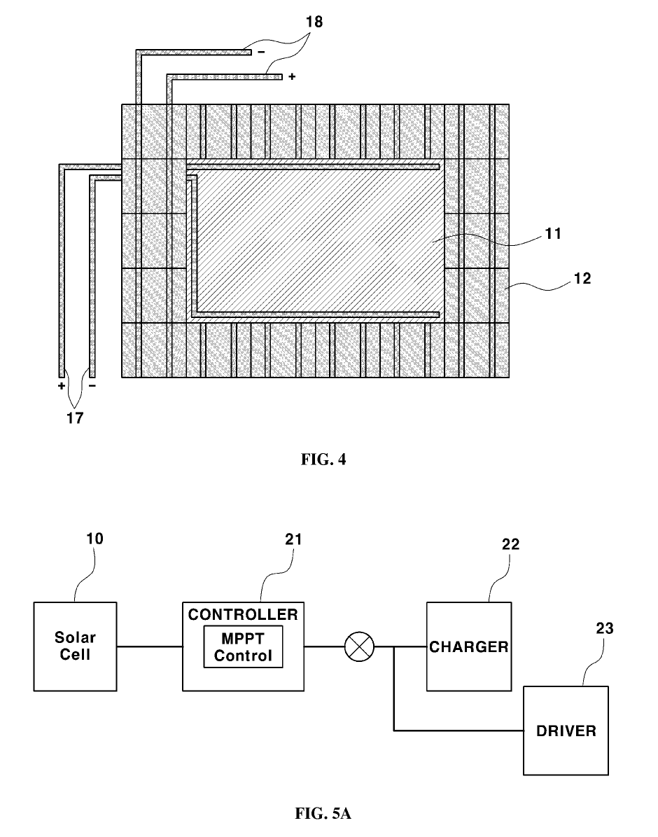

FIG. 4 illustrates the first electric wire part 17 which is connected to the first solar cell 11 and the second electric wire part 18 which is connected to the second solar cell 12. In the case of the heterogeneous solar cells having different output voltages, the output voltage of each solar cell may be used, and therefore the electric wire parts may each be connected to the same kind of solar cells. Therefore, the output voltages of different kinds of solar cells may be used by being divided. In this case, it is possible to reduce the power loss of the solar cell which appears through one wiring processing.

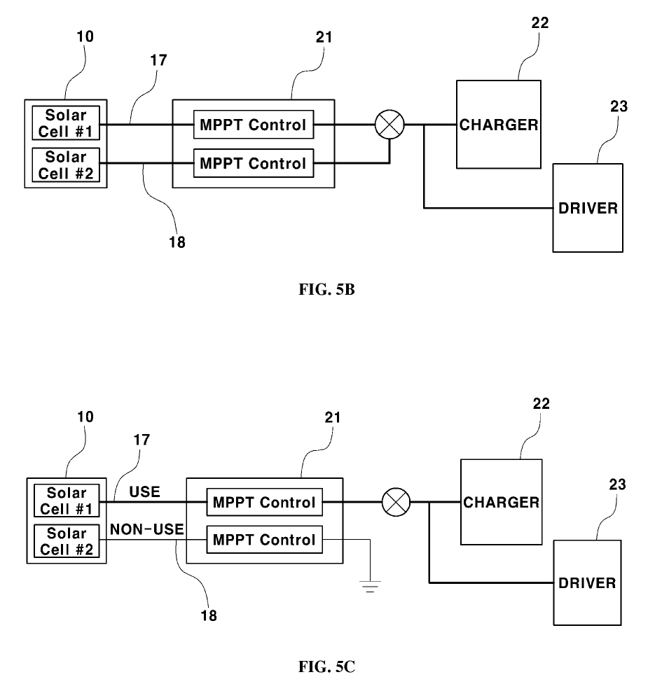

FIG. 5A schematically illustrates the connection between the roof panel 10 having a solar cell and the controller, and between the driver 23 and the battery. The roof panel 10 having a solar cell of FIG. 5A is configured of the first solar cell 11 and the second solar cell 12 which are connected to the controller 21 by handling the first electric wire part 17 and the second electric wire part 18 as a single wiring. More preferably, the controller 21 may be configured of a maximum power point tracking (MPPT) controller.

As illustrated in FIG. 5A, when the electric parts handled as the single wiring are provided, the output voltages of different kinds of solar cells are maintained to be equal and thus power loss is minimized Any one of the first solar cell and the second solar cell 12 is configured in a cell form and the output voltages of respective solar cells may be constantly maintained through the serial and parallel arrangement of the cells. The controller 21 may control the output of the solar cell to the charger 22 of the battery or the driver 23 in real time. The connection control between the solar cell and the charger 22 and the driver 23 by the controller 21 is performed by an electronic switching.

FIG. 5B illustrates a state in which the first electric wire 17 and the second electric wire 18 of the roof panel 10 having a solar cell are each connected to the controller 21. That is, since the first electric wire part 17 which is connected to the electrode of the first solar cell 11 is connected to the first controller 21 and the second electric wire part 18 which is connected to the electrode of the second solar cell 12 is connected to the second controller 21, when the output voltages of the first solar cell 11 and the second solar cell 12 are not the same, the output voltages of the heterogeneous solar cells may be independently used. As such, the first electric wire part 17 and the second electric wire part 18 which are connected depending on the power which is generated from the first solar cell 11 and the second solar cell 12 may each be connected to the charger 22 of the battery or the driver 23 by the first and second controllers 21.

FIG. 5C illustrates the configuration in which since the controller 21 connected to the first electric wire part 17 performs conduction and the controller 21 connected to the second electric wire part 18 is opened, the power generated from the first solar cell 11 is transferred to the charger 22 of the battery and the driver 23.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A roof panel having a solar cell of a vehicle in which heterogeneous solar cells are disposed in a roof glass, comprising:
a first solar cell configured to be mounted at a central portion of the roof glass; and
a second solar cell having transparency lower than that of the first solar cell configured to be mounted at an edge portion of the roof glass,
wherein upper and lower surfaces of the first solar cell and the second solar cell are sequentially stacked with a bonding film and the roof glass,
at least one of the first solar cell and the second solar cell is configured of a plurality of cells and the plurality of cells of the solar cell are connected in series and in parallel so that output voltages of the solar cells are the same, and
the first solar cell and the second solar cell are adjacently positioned to each other, maintaining a gap to prevent the first solar cell and the second solar cell from contacting each other.

2. The roof panel of claim 1, wherein the first solar cell and the second solar cell are formed of different thicknesses and further include filling films to offset a difference in thickness between the first solar cell and the second solar cell.

3. The roof panel of claim 1, wherein in the case of the solar cell configured of the plurality of cells, the cells have the same size.

4. The roof panel of claim 1, wherein the first solar cell is selected from the group consisting of: a dye-sensitive solar cell, an amorphous silicon solar cell, an organic solar cell, a perovskite-based solar cell, a quantum dot solar cell, and combination of at least two thereof.

5. The roof panel of claim 1, wherein the second solar cell is selected from the group consisting of: a crystalline silicon solar cell, a cadmium-telluride (CdTe) solar cell, a copper-indium-gallium-selenium (CIGS) solar cell, and a combination of at least two thereof.

6. The roof panel of claim 1, wherein a constant gap between the first solar cell and the second solar cell is filled with an insulator.

7. A roof panel having a solar cell of a vehicle in which heterogeneous solar cells are disposed in a roof glass, comprising:
a first solar cell configured to be mounted at a central portion of the roof glass;
a second solar cell having transparency lower than that of the first solar cell configured to be mounted at an edge portion of the roof glass;
a first electric wire part configured to be connected to an electrode of the first solar cell;
a second electric wire part configured to be connected to an electrode of the second solar cell; and
a plurality of controllers configured to be connected to the first electric wire part and the second electric wire part, respectively,
wherein upper and lower surfaces of the first solar cell and the second solar cell are stacked with a bonding film, and
the first solar cell and the second solar cell are adjacently positioned to each other, maintaining a gap to prevent the first solar cell and the second solar cell from contacting each other.

8. The roof panel of claim 7, wherein the plurality of controllers control a connection between a charger and a driver depending on outputs of the solar cells.

9. The roof panel of claim 7, wherein at least one of the plurality of controllers receives information measured by a positional information sensor of the vehicle which measures positional information of the sun, a geomagnetic sensor which measures a slope of the vehicle, and a tilt sensor which measures a slope of the roof panel and controls the slope of the roof channel depending on the received information.

10. The roof panel of claim 7, wherein at least one of the plurality of controllers is configured of a maximum power point tracking (MPPT) controller.

11. The roof panel of claim 7, wherein the first solar cell is selected from the group consisting of: a dye-sensitive solar cell, an amorphous silicon solar cell, an organic solar cell, a perovskite-based solar cell, a quantum dot solar cell, and a combination of at least two thereof.

12. The roof panel of claim 7, wherein the second solar cell is selected from the group consisting of: a silicon solar cell, a cadmium-telluride (CdTe) solar cell, a copper-indium-gallium-selenium (CIGS) solar cell, and a combination of at least two thereof.

13. The roof panel of claim 7, wherein a constant gap between the first solar cell and the second solar cell is filled with an insulator to prevent the first solar cell and the second solar cell from contacting each other.
